(19) United States
(12) Patent Application Publication
(10) Pub. No.: US 2015/0013743 A1
(43) Pub. Date: Jan. 15, 2015

(54) SOLAR CELL MODULE

(71) Applicant: AU Optronics Corporation, HSIN-CHU (TW)

(72) Inventor: Shih-Hsien YANG, Hsin-Chu (TW)

(73) Assignee: AU Optronics Corporation, Hsin-Chu (TW)

(21) Appl. No.: 14/136,173

(22) Filed: Dec. 20, 2013

(30) Foreign Application Priority Data
Jul. 10, 2013 (CN) 201310288858.8

(51) Int. Cl. H01L 31/055

(52) U.S. Cl. CPC H01L 31/055
USPC 136/244; 136/257

(57) ABSTRACT

A solar cell module includes a front plate, at least one solar cell chip, and at least one anti-ultraviolet light element. The front plate has at least one anti-ultraviolet light segment and at least one light receiving segment. The solar cell chip is disposed at one side of the front plate, and a vertical projection of the light receiving segment of the front plate overlaps at least one portion of the solar cell chip. The anti-ultraviolet light element is disposed at the other side of the front plate opposite to the solar cell chip, and covers the anti-ultraviolet light segment of the front plate but exposes the light receiving segment of the front plate. The anti-ultraviolet light element allows visible light to pass therethrough, but blocks the ultraviolet light.

### RELATED APPLICATIONS

This application claims priority to Chinese Application Serial Number 201310288858.8, filed Jul. 10, 2013, which is herein incorporated by reference.

### BACKGROUND

1. Field of Invention

The present invention relates to a solar cell module.

2. Description of Related Art

Owing to continuous consumption of petroleum energy, the industry of solar energy, the important one of alternate energy sources, is rapidly developed recently. The technology of solar energy is utilizing a solar cell to absorb the sunshine, and converting the solar energy to the electrical energy in the solar cell.

The solar cell may be designed to increase the absorption ability of ultraviolet light so that the conversion efficiency and the efficiency of electric power generation are improved in the meantime. However, after exposed to the ultraviolet light for a long period, the components in the solar cell may become yellowing and aging. The components with yellowing and/or aging may affect the function of the solar cell such that the efficiency of electric power generation for the solar cell is decreased.

### SUMMARY

One aspect of this invention provides a solar cell module including a front plate, at least one solar cell chip, and at least one anti-ultraviolet light element. The front plate has at least one anti-ultraviolet light segment and at least one light receiving segment. The solar cell chip is disposed at one side of the front plate, and a vertical projection of the light receiving segment of the front plate overlaps at least a portion of the solar cell chip. The anti-ultraviolet light element is disposed at the other side of the front plate opposite to the solar cell chip, and covers the anti-ultraviolet light segment of the front plate but exposes the light receiving segment of the front plate. The anti-ultraviolet light element allows visible light to pass therethrough, but blocks ultraviolet light.

Another aspect of this invention provides a solar cell module including a front plate, a solar cell body, and at least one anti-ultraviolet light element. The front plate has at least one anti-ultraviolet light segment and at least one light receiving segment. The solar cell body is disposed at the back of the front plate. The solar cell body has at least one yellowing material with a yellowness index which is greater than or equal to 2 under an ultraviolet exposure dose of 15 KWH/m². The vertical projection of the anti-ultraviolet light segment of the front plate overlaps at least a portion of the yellowing material. The anti-ultraviolet light element covers the anti-ultraviolet light segment of the front plate but exposes the light receiving segment of the front plate. The anti-ultraviolet light segment allows visible light to pass therethrough, but blocks ultraviolet light.

### BRIEF DESCRIPTION OF THE DRAWINGS

FIG. 1 is a partial top view of the solar cell module according to one embodiment of this invention;

FIG. 2 is a cross-section view along line 2-2 of FIG. 1;

FIG. 3 is a partial enlarged view of the region M in FIG. 2;

FIG. 4 is a partial enlarged view of the anti-ultraviolet light element in FIG. 2;

FIG. 5 is a partial top view of the solar cell module according to another embodiment of this invention;

FIG. 6 is a cross-section view along line 6-6 of FIG. 5;

FIG. 7 is a cross-section view of the solar cell module according to yet another embodiment of this invention;

FIG. 8 is a partial top view of the solar cell module according to further another embodiment of this invention; and

FIG. 9 is a cross-section view along line 9-9 of FIG. 8.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically depicted in order to simplify the drawings.

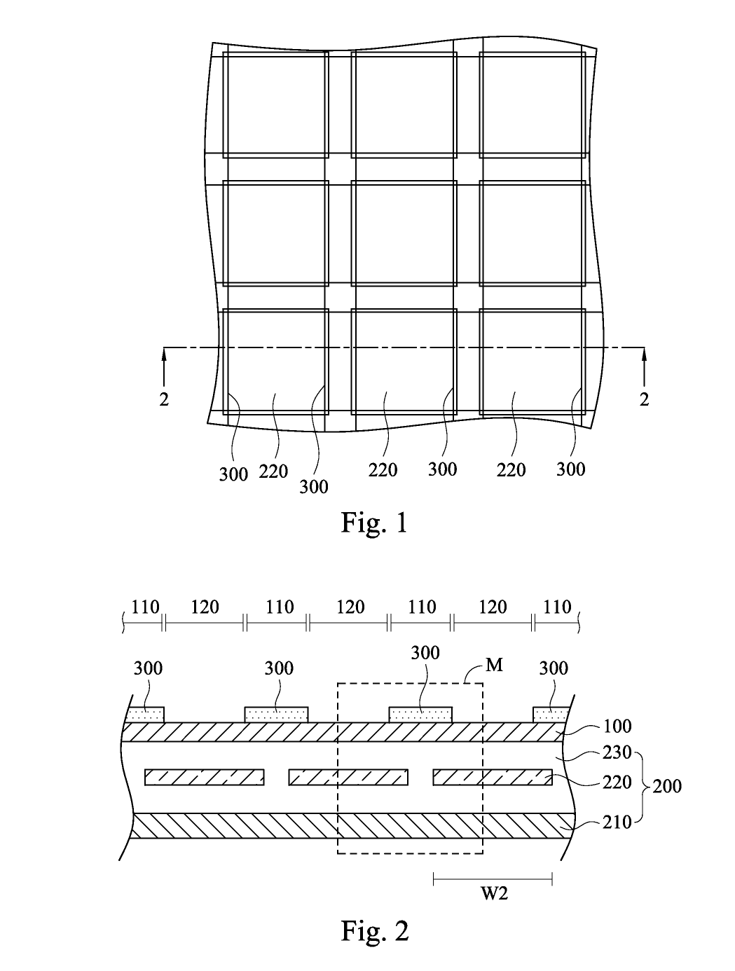

Referring to FIG. 1 and FIG. 2. FIG. 1 is a partial top view of the solar cell module according to one embodiment of this invention, and FIG. 2 is a cross-section view along line 2-2 of FIG. 1. The solar cell module includes a front plate 100, a solar cell body 200, and at least one anti-ultraviolet light element 300. The front plate 100 has at least one anti-ultraviolet light segment 110 and at least one light receiving segment 120. The solar cell body 200 is disposed at the back of the front plate 100 so that the sunshine can illuminate the solar cell body 200 through the front plate 100. The solar cell body 200 includes a back plate 210 and at least one solar cell chip 220. The back plate 210 and the front plate 100 are disposed separately. The vertical projection of the anti-ultraviolet light segment 110 of the front plate 100 overlaps at least portion of the back plate 210. The solar cell chip 220 is disposed between the front plate 100 and the back plate 210. The vertical projection of the light receiving segment 120 of the front plate 100 overlaps at least a portion of the solar cell chip 220. The anti-ultraviolet light element 300 is disposed at the other side of the front plate 100 opposite to the solar cell chip 220, and covers the anti-ultraviolet light segment 110 of the front plate 100, but exposes the light receiving segment 120 of the front plate 100. Accordingly, because the light receiving segment 120 of the front plate 100 is not covered by the anti-ultraviolet light element 300, the ultraviolet light may reach the solar cell chip 220 through the light receiving segment 120, such that the incidence light quantity of the solar cell chip 220 is increased. It should be noted that although the solar cell chip 220 is disposed below the anti-ultraviolet light element 300 and the front plate 100 in FIG. 1 (as shown in FIG. 2), the anti-ultraviolet light element 300 and the front plate 100 are transparent for visible light in this embodiment, so that the solar cell chip 220 is visible from the top view of FIG. 1.

In this embodiment, the back plate 210 may be a yellowing material, that is, the plate 210 become yellowing gradually after exposed to the ultraviolet light for a long period. However, because the solar cell chip 220 may absorb the ultraviolet light, the portion of the back plate 210 under the solar cell chip 220 is almost not illuminated by the ultraviolet light. The ultraviolet light may illuminate the other portion of the back plate 210 through the surrounding of the solar cell chip 220. Therefore, this portion of ultraviolet light can be blocked by the anti-ultraviolet light element 300. In other words, the vertical projection of the anti-ultraviolet light segment 110 of the front plate 100 can at least surround the solar cell chip 220, and the light receiving segment 120 can be complemented with the anti-ultraviolet light segment 110. Thus, the ultraviolet light can be blocked by the anti-ultraviolet light element 300 and the solar cell chip 220, and the back plate 210 can be avoided to be illuminated from the ultraviolet light.

If only considering the ultraviolet light orthogonally being incident the front plate 100 (that is, the sunshine being incident the front plate 100 along the normal vector of the front plate 100), the vertical projection of the light receiving segment 120 of the front plate 100 may optionally overlap the solar cell chip 220 entirely, and the position of the light receiving segment 120 can be complemented with that of the anti-ultraviolet light segment 110. Thus, the orthogonal ultraviolet light almost may not illuminate the back plate 210, meanwhile the solar cell chip 220 may receive most of the ultraviolet light. However, if considering the ultraviolet light being incident the front plate 100 obliquely (that is, the sunshine being incident the front plate along 100 with an angle more than zero degrees related to the normal vector of the front plate 100), the area of the anti-ultraviolet light segment 110 may be larger to prevent the obliquely incident ultraviolet light from illuminating the back plate 210 through the surrounding of the anti-ultraviolet light element 300 and the solar cell chip 220.

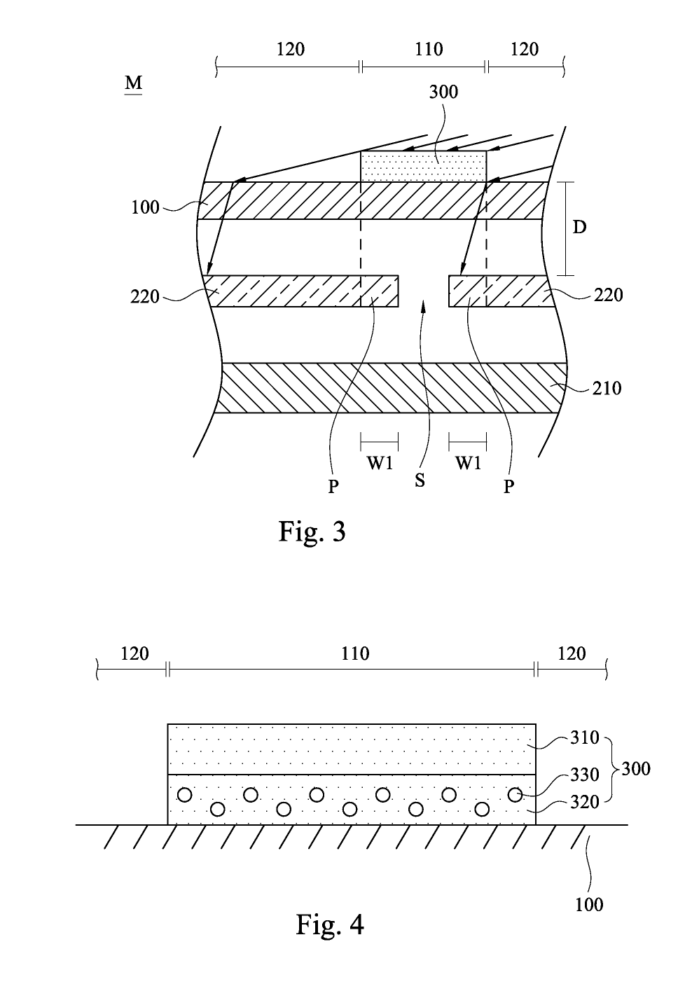

For example, please refer to FIG. 3. FIG. 3 is a partial enlarged view of the region M in FIG. 2. In this embodiment, the quantity of the solar cell chip 200 may be plural, and every adjacent two of the solar cell chips 220 have a space S. In other words, the ultraviolet light may reach the back plate 210 through the space S, thus the vertical projection of the anti-ultraviolet light segment 110 may overlap at least portion of the space S. Such as shown in FIG. 3, the vertical projection of the anti-ultraviolet light segment 110 overlaps the space S. In order to block the ultraviolet light being incident obliquely, the anti-ultraviolet light element 300 can form vertical projections P on the solar cell chips 220, respectively. Each of the vertical projections P has a width W1. The width W1 can be determined by the entering direction of the ultraviolet light and the distance between the anti-ultraviolet light element 300 and the solar cell chip 220. In greater detail, the front plate 100 has an angle of total reflection θ, that is, the refraction angle of the ultraviolet light being incident the front plate 100 is less than or equal to the angle of total reflection θ. The vertical distance between the anti-ultraviolet light element 300 and the solar cell chip 220 is D. Thus the relationship of the width W1, the angle of total reflection θ, and the vertical distance D can be shown as following:

W1≧D tan θ.

However, the light receiving segment 120 which allows the solar cell chip 220 to receive the ultraviolet light can be further considered. If the solar cell chip 220 has a width W2 (see FIG. 2), it is optional as following:

(W2)/2>W1, that is,

(W2)/2>W1≧D tan δ.

Therefore, after the ultraviolet light is incident the front plate 100 obliquely, it is refracted at an angle less than or equal to the angle of total reflection θ. According to the relationship formula above, any ultraviolet light being incident the front plate 100 may reach the solar cell chip 220 (see FIG. 3), but not reach the space S. In other words, if the vertical projection P has the width W1, the orthogonal ultraviolet light and the oblique ultraviolet light can both be prevented from being incident the back plate 210.

In this embodiment, the yellowing material is defined with a yellowness index which is greater than or equal to 2 under an ultraviolet light exposure dose of 15 KWH/m². Under exposing to ultraviolet light for a long period, the back plate 210 may become yellowing so that the operation of the solar cell is affected and the efficiency of electric power generation for the solar cell is decreased. However, the anti-ultraviolet light element 300 of this embodiment may improve the issue above.

Then, please refer to FIG. 2. In one or more embodiments, the solar cell body 200 may further include a sealant 230. The sealant 230 is disposed between the front plate 100 and the back plate 210 and covers the solar cell chips 220. The sealant 230 may provide the isolation protection for the solar cell chips 220, and also may provide a proper mechanical strength and a good heat dissipation. The material of the sealant 230 can be Ethylene Vinyl Acetate (EVA), but not limits to this material.

In order to further improve the ultraviolet receiving quantity of the solar cell chip 220, the material of the sealant 230 may be selected from a transparent material for ultraviolet light (for example, EVA, but not limits to this).

Please refer to FIG. 4. FIG. 4 is a partial enlarged view of the anti-ultraviolet light element 300 in FIG. 2. In one or more embodiments, the anti-ultraviolet light element 300 may include a film 310, a glue layer 320, and a plurality of ultraviolet absorbing particles 330. The glue layer 320 is configured for adhering the film 310 on the anti-ultraviolet light segment 110 of the front plate 100, and the ultraviolet absorbing particles 330 are disposed in the glue layer 320. In greater detail, the anti-ultraviolet light element 300 is formed by laminating the film 310 and the glue layer 320. In the laminating process, the ultraviolet absorbing particles 330 are disposed in the glue layer 320 in advance so that the anti-ultraviolet light element 300 may absorb and block the ultraviolet light. It should be noted that because the visible light only slightly affects the yellowing material, the anti-ultraviolet light element 300 can allow visible light to pass therethrough, but blocks the ultraviolet light. The material of the film 310 may be Polyethylene (PE), and the material of the glue layer 320 may be polymethylmethacrylate (PMMA, acrylic) or Polyethylene (PE).

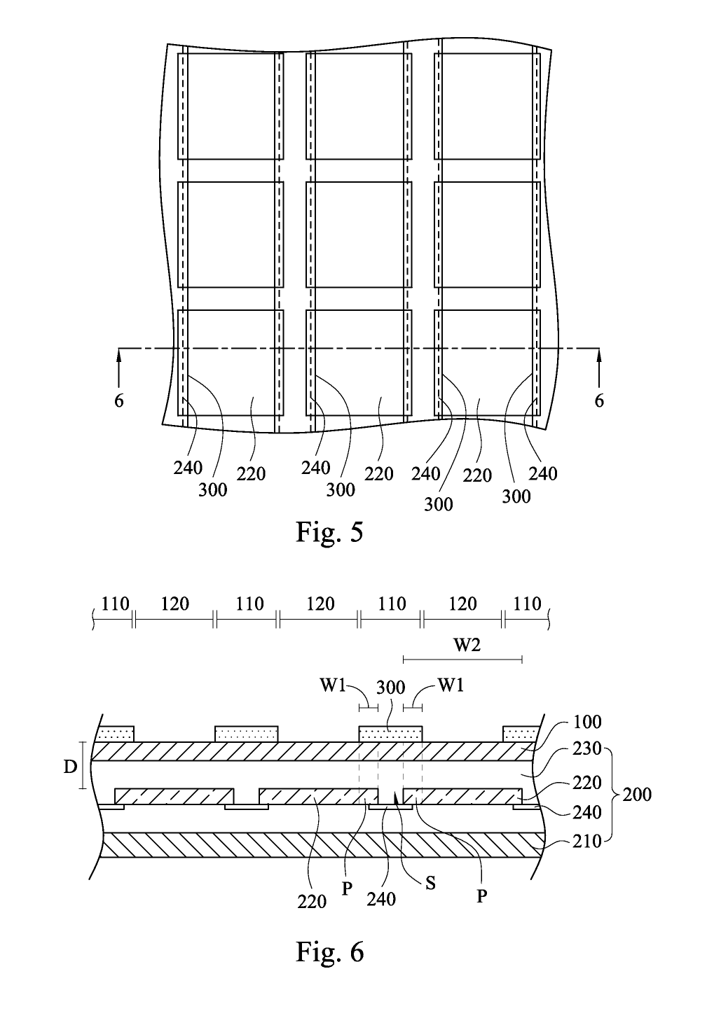

Please refer to FIG. 5 and FIG. 6. FIG. 5 is a partial top view of the solar cell module according to another embodiment of this invention, and FIG. 6 is a cross-section view along line 6-6 of FIG. 5. The differences between this embodiment and the embodiment in FIG. 1 are the addition of a fixing glue 240 and the material of the back plate 210. In this embodiment, the solar cell body 200 can further include the fixing glue 240. The fixing glue 240 is configured for adhering two adjacent of the solar cell chips 220. The fixing glue 240 is disposed on the side of the solar cell chips 220 opposite to the front plate 100, and the vertical projection of the anti-ultraviolet light segment 110 of the front plate 100 overlaps at least a portion of the fixing glue 240.

In this embodiment, the fixing glue 240 is a yellowing material. In greater detail, portions of the fixing glue 240 is located below the solar cell chips 220, thus these portions may not be illuminated by the ultraviolet light. However, the ultraviolet light may illuminate the other portion of the fixing glue 240 through the space S between two adjacent of the solar cell chips 220, so that this portion of the ultraviolet light may be blocked by the anti-ultraviolet light element 300. In other words, the vertical projection of the anti-ultraviolet light segment 110 may optionally overlap at least a portion of the space S. For example, as shown in FIG. 6, the vertical projection of the anti-ultraviolet light segment 110 covers the space S. Furthermore, in order to block the oblique ultraviolet light, the anti-ultraviolet light element 300 may form a vertical projection P on each of the solar cell chips 220, respectively. Each of the vertical projections P has a width W1. In practice, the front plate 100 has an angle of total reflection θ, and the vertical distance between the anti-ultraviolet light element 300 and the solar cell chip 220 is D. Thus, the relationship of the width W1, the angle of total reflection θ, and the vertical distance D can be shown as following:

W1≧D tan θ.

However, the light receiving segment 120 which allows the solar cell chip 220 to receive the ultraviolet light can be considered. If the solar cell chip 220 has a width W2, it is optional as following:

(W2)/2>W1, that is

(W2)/2>W2≧D tan θ.

Therefore, after the ultraviolet light is incident the front plate 100 obliquely, it is refracted at an angle less than or equal to the angle of total reflection θ. According to the relationship formula above, any ultraviolet light being incident the front plate 100 may reach the solar cell chip 220, but not reach the space S. In other words, if the vertical projection P has the width W1, the orthogonal ultraviolet light and the oblique ultraviolet light can both be prevented from being incident the fixing glue 240.

It should be noted that, although the formula (W2)/2>W1≧D tan θ is obtained from the yellowing material such as the fixing glue 240 and the back plate 210 utilized respectively in this embodiment and the embodiment of FIG. 2, this invention is not limited to this two embodiments. In other embodiments, the formula (W2)/2>W1≧D tan θ can be suitable for use if the solar cell chips 220 are disposed between the yellowing material and the front plate 100.

In one or more embodiments, the back plate 210 may be formed of an anti-yellowing material, for example, Tedlar/Polyster/Tedlar (TPT) to implement the anti-ultraviolet effect. However, it should be noted that the material of the back plate 210 above is only an example and not to limit this invention. A person having ordinary skills in the art may select a proper material of the back plate 210 according to real requirements. Other relevant structural details of the embodiment are all the same as the embodiment of FIG. 1, and, therefore, a description in this regard will not be repeated hereinafter.

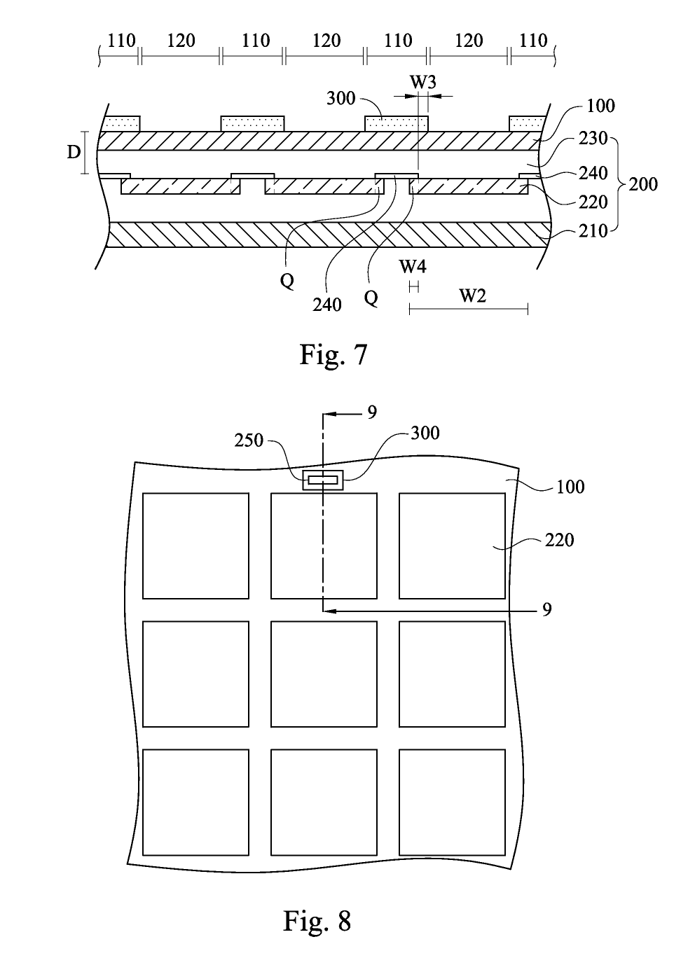

Please refer to FIG. 7. FIG. 7 is a cross-section view of the solar cell module according to yet another embodiment of this invention. The difference between this embodiment and the embodiment in FIG. 6 is the location of the fixing glue 240. In this embodiment, the fixing glue may be disposed between the solar cell chips 220 and the front plate 100. If the anti-ultraviolet light element 300 is not utilized, the ultraviolet light may directly illuminate the fixing glue 240 through the front plate 100. Thus, the vertical projection of the anti-ultraviolet light segment 110 can overlap at least a portion of the fixing glue 240. Taking FIG. 7 as an example, the vertical projection of the anti-ultraviolet light segment 110 covers the fixing glue 240.

Moreover, in order to block the oblique ultraviolet light, the edge of the vertical projection of the fixing glue 240 on front plate 100 is separated from the edge of the anti-ultraviolet light segment 110 with a shortest distance W3. The vertical projection here is defined as the portion of the front plate 100 overlapped by the fixing glue 240 along the viewing direction from the back plate 210 to the front plate 100. When the vertical distance between the anti-ultraviolet light element 300 and the fixing glue 240 is D, and the front plate 100 has an angle of total reflection θ, the relationship of the shortest distance W3, the angle of total reflection θ, and the vertical distance D can be shown as following:

W3≧D tan θ.

However, the light receiving segment 120 which allows the solar cell chip 220 to receive the ultraviolet light can be considered. If the solar cell chip 220 has a width W2, the fixing glue 240 may form a vertical projection Q on each of the solar cell chips 220, respectively, and each of the vertical projections Q has a width W4, it is optional as following:

((W2)/2−W4)>W3, that is,

((W2)/2−W4)>W3≧D tan θ.

Other relevant structural details of the embodiment are all the same as the embodiment of FIG. 6, and, therefore, a description in this regard will not be repeated hereinafter.

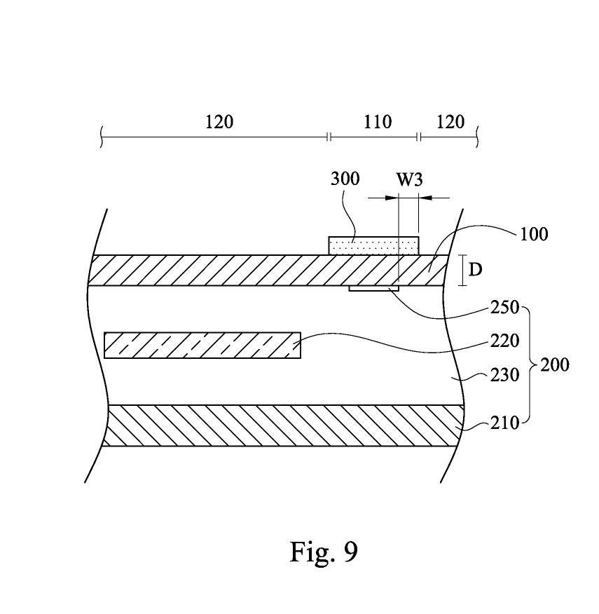

Please refer to FIG. 8 and FIG. 9. FIG. 8 is a partial top view of the solar cell module according to further another embodiment of this invention, and FIG. 9 is a cross-section view along line 9-9 of FIG. 8. The differences between this embodiment and the embodiment in FIG. 5 and FIG. 6 are the addition of a label 250 and the lack of the fixing glue 240 (see FIG. 6). In this embodiment, the solar cell body 200 can further include the label 250 disposed between the sealant 230 and the front plate 100. The vertical projection of the anti-ultraviolet light segment 110 can overlap at least a portion of the label 250. Taking FIG. 9 as an example, the vertical projection of the anti-ultraviolet light segment 110 covers the label 250. It should be noted that although the label 250 is disposed below the anti-ultraviolet light element 300 and the front plate 100 (see FIG. 9), the label 250 is visible from the top of the solar cell module in the top view of FIG. 8 since the anti-ultraviolet light element 300 and the front plate 100 are transparent for visible light in this embodiment.

In this embodiment, the label 250 is a yellowing material. Taking FIG. 9 as an example, when the ultraviolet light is incident the front plate 100 orthogonally, the anti-ultraviolet light element 300 may block the ultraviolet light being incident the label 250. In addition, the size of the anti-ultraviolet light element 300 may be designed to block the ultraviolet light being incident the front plate 100 obliquely. In greater detail, the edge of the vertical projection of the label 250 on front plate 100 is separated from the edge of the anti-ultraviolet light segment 110 with a shortest distance W3. The vertical projection here is defined as the portion of the front plate 100 overlapped by the label 250 along the viewing direction from the back plate 210 to the front plate 100. When the vertical distance between the anti-ultraviolet light element 300 and the label 250 is D, and the front plate 100 has an angle of total reflection θ, the relationship of the shortest distance W3, the angle of total reflection θ, and the vertical distance D can be shown as following:

W3≧D tan θ.

It should be noted that, although the formula W3≧D tan θ is obtained from the label 250 and the fixing glue 240 utilized as the yellowing material respectively in this embodiment and the embodiment of FIG. 7, this invention is not limited to this two embodiments. In other embodiments, the formula W3≧D tan θ is suitable for use if the yellowing material is disposed between the solar cell chips 220 and the front plate 100. Other relevant structural details of the embodiment are all the same as the embodiment of FIG. 5 and FIG. 6, and, therefore, a description in this regard will not be repeated hereinafter.

Moreover, although the yellowing material may merely be a single element in the four embodiments above, the yellowing materials may be of different kinds. Regarding these cases, the anti-ultraviolet light segment 110 of the front plate 100 may be the union of the anti-ultraviolet light segments 110 corresponding to individual embodiments. That is, if the ultraviolet may illuminate any one of the yellowing materials, the anti-ultraviolet light element 300 cab be disposed on the front plate 100 respectively.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A solar cell module, comprising:
a front plate having at least one anti-ultraviolet light segment and at least one light receiving segment;
at least one solar cell chip disposed at one side of the front plate, wherein a vertical projection of the light receiving segment of the front plate overlaps at least portion of the solar cell chip; and
an anti-ultraviolet light element disposed at the other side of the front plate opposite to the solar cell chip, wherein the anti-ultraviolet light element covers the anti-ultraviolet light segment of the front plate but exposes the light receiving segment of the front plate, and wherein the anti-ultraviolet light element allows visible light to pass therethrough, but blocks ultraviolet light.

2. The solar cell module of claim 1, wherein the anti-ultraviolet light element comprises:
a film;
a glue layer adhering the film and the anti-ultraviolet light segment of the front plate; and
a plurality of ultraviolet absorbing particles disposed in the glue layer.

3. The solar cell module of claim 1, wherein a space is formed between two adjacent of the solar cell chips, and the vertical projection of the light receiving segment of the front plate overlaps at least a portion of the space.

4. The solar cell module of claim 3, wherein a vertical distance between the anti-ultraviolet light element and one of the solar cell chips is D, the anti-ultraviolet light element forms a vertical projection on the solar cell chips respectively, and each of the vertical projections has a width W1, wherein each of the solar cell chips has a width W2, the front plate has an angle of total reflection θ, and the relationship of the width W1, W2, the angle of total reflection θ, and the vertical distance D is as following:
(W2)/2>W1≧D tan θ.

5. The solar cell module of claim 1, further comprising a back plate, wherein the solar cell chip is disposed between the front plate and the back plate.

6. The solar cell module of claim 5, wherein the material of the back plate is Tedlar/Polyster/Tedlar (TPT).

7. The solar cell module of claim 1, further comprising:
a sealant covering the solar cell chip.

8. The solar cell module of claim 7, further comprising:
at least one label disposed between the sealant and the front plate, wherein a vertical projection of the anti-ultraviolet light segment of the front plate overlaps at least a portion of the label.

9. The solar cell module of claim 8, wherein a vertical distance between the anti-ultraviolet light element and the label is D, the label forms a vertical projection on the front plate, and the edge of the vertical projection of the label is separated from the edge of the anti-ultraviolet light segment with a shortest distance W3, the front plate has an angle of total reflection θ, and the relationship of the shortest distance W3, the angle of total reflection θ, and the vertical distance D is as following:
W3≧D tan θ.

10. The solar cell module of claim 7, wherein the material of the sealant is a transparent material for an ultraviolet light.

11. The solar cell module of claim 1, further comprising:
a fixing glue adhering two adjacent of the solar cell chips, and a vertical projection of the anti-ultraviolet light segment of the front plate overlaps at least a portion of the fixing glue.

12. A solar cell module, comprising:
a front plate having at least one anti-ultraviolet light segment and at least one light receiving segment;
a solar cell body disposed at the back of the front plate, wherein the solar cell body has at least one yellowing material with a yellowness index which is greater than or equal to 2 under an ultraviolet exposure dose of 15 KWH/m², and a vertical projection of the anti-ultraviolet light segment of the front plate overlaps at least a portion of the yellowing material; and
at least one anti-ultraviolet light element covering the anti-ultraviolet light segment of the front plate but exposes the light receiving segment of the front plate, wherein the anti-ultraviolet light segment allows visible light to pass therethrough, but blocks ultraviolet light.

13. The solar cell module of claim 12, wherein the anti-ultraviolet light element comprises:
a film;
a glue layer adhering the film and the anti-ultraviolet light segment of the front plate; and
a plurality of ultraviolet absorbing particles disposed in the glue layer.

14. The solar cell module of claim 12, wherein the yellowing material of the solar cell body is a back plate, the back plate and the front plate are disposed separately, and
wherein the solar cell body further comprises:
at least one solar cell chip disposed between the front plate and the back plate, wherein a vertical projection of the light receiving segment of the front plate overlaps at least a portion of the solar cell chip.

15. The solar cell module of claim 12, wherein the solar cell body further comprises:
a back plate separated from the front plate;
a plurality of solar cell chips disposed between the front plate and the back plate, wherein a vertical projection of the light receiving segment of the front plate overlaps at least a portion of the solar cell chips; and
wherein the yellowing material of the solar cell body is a fixing glue, and the fixing glue adheres two adjacent of the solar cell chips.

16. The solar cell module of claim 15, wherein the material of the back plate is Tedlar/Polyster/Tedlar (TPT).

17. The solar cell module of claim 12, wherein the solar cell body further comprises a plurality of solar cell chips disposed between the front plate and the yellowing material, a vertical distance between the anti-ultraviolet light element and one of the solar cell chips is D, the anti-ultraviolet light element forms a vertical projection on two adjacent of the solar cell chips respectively, and each of the vertical projections has a width W1, each of the solar cell chips has a width W2, the front plate has an angle of total reflection θ, and the relationship of the width W1, W2, the angle of total reflection θ, and the vertical distance D is as following:
(W2)/2>W1≧D tan θ.

18. The solar cell module of claim 12, wherein the solar cell body further comprises:
a back plate separated from the front plate;
at least one solar cell chip disposed between the front plate and the back plate, wherein a vertical projection of the light receiving segment of the front plate overlaps at least a portion of the solar cell chip; and
a sealant disposed between the front plate and the back plate and covering the solar cell chip,
wherein the yellowing material of the solar cell body is a label disposed between the sealant and the front plate.

19. The solar cell module of claim 18, wherein the material of the sealant is a transparent material for an ultraviolet light.

20. The solar cell module of claim 18, wherein the material of the back plate is Tedlar/Polyster/Tedlar (TPT).

21. The solar cell module of claim 12, wherein the solar cell body includes at least one solar cell chip, and the yellowing material is disposed between the front plate and the solar cell chip, a vertical distance between the anti-ultraviolet light element and the yellowing material is D, the yellowing material forms a vertical projection on the front plate, and the edge of the vertical projection of the yellowing material is separated from the edge of the anti-ultraviolet light segment with a shortest distance W3, the front plate has an angle of total reflection θ, and the relationship of the shortest distance W3, the angle of total reflection θ, and the vertical distance D is as following:
W3≧D tan θ.
